(19) United States
(12) Patent Application Publication
(10) Pub. No.: US 2024/0032432 A1
(43) Pub. Date: Jan. 25, 2024

(54) DRIVE ELEMENT

(71) Applicant: Panasonic Intellectual Property Management Co., Ltd., Osaka (JP)

(72) Inventors: Shoji OKAMOTO, Osaka (JP); Ryouichi TAKAYAMA, Osaka (JP); Takuma KATAYAMA, Kyoto (JP)

(21) Appl. No.: 18/374,579

(22) Filed: Sep. 28, 2023

Related U.S. Application Data
(63) Continuation of application No. PCT/JP2022/006561, filed on Feb. 18, 2022.

(30) Foreign Application Priority Data
Mar. 30, 2021 (JP) 2021-057251
Apr. 23, 2021 (JP) 2021-073524

(51) Int. Cl. H10N 30/87; H02N 2/10; H02N 2/00; H10N 30/853; H10N 30/082; H10N 30/06

(52) U.S. Cl. CPC H10N 30/87; H02N 2/108; H02N 2/22; H10N 30/8548; H10N 30/082; H10N 30/06; G02B 26/0858

(57) ABSTRACT

A drive element includes: a fixing part; a drive part placed on a lateral side of the fixing part and coupled to the fixing part; and a movable part configured to be driven by the drive part. A lower electrode, a piezoelectric layer, and an upper electrode are formed in order in an upper surface region of the fixing part and the drive part, and in a wiring region on the fixing part side of the upper surface region, a low dielectric layer containing at least one element forming the piezoelectric layer is formed on an upper surface of the piezoelectric layer.

### CROSS REFERENCE TO RELATED APPLICATION

This application is a continuation of International Application No. PCT/JP2022/006561 filed on Feb. 18, 2022, entitled “DRIVE ELEMENT”, which claims priority under 35 U.S.C. Section 119 of Japanese Patent Application No. 2021-057251 filed on Mar. 30, 2021, entitled “DRIVE ELEMENT” and Japanese Patent Application No. 2021-073524 filed on Apr. 23, 2021, entitled “DRIVE ELEMENT”. The disclosures of the above applications are incorporated herein by reference.

### BACKGROUND OF THE INVENTION

### Field of the Invention

The present invention relates to a drive element in which a piezoelectric layer is placed.

### Description of Related Art

In recent years, various devices have been developed using drive elements in which piezoelectric layers are placed. Japanese Patent No. 5903667 describes an inertial force sensor including: a substrate; a lower electrode layer formed on the upper surface of the substrate; a piezoelectric layer formed on the upper surface of the lower electrode layer; a capacitance reduction layer formed on the upper surface of the piezoelectric layer; and an upper electrode layer formed on the upper surface of the capacitance reduction layer. The capacitance reduction layer is formed from polyimide.

In the sensor described above, due to manufacturing, the lower electrode layer, the piezoelectric layer, and the upper electrode layer are also formed so as to extend in a region for wiring. In Japanese Patent No. 5903667, the capacitance reduction layer is placed in order to suppress noise and unnecessary vibrations in this region. However, in the above lamination structure in which the capacitance reduction layer, which is formed from polyimide, is stacked on the upper surface of the piezoelectric layer, the capacitance reduction layer may peel off from the upper surface of the piezoelectric layer.

### SUMMARY OF THE INVENTION

A drive element according to a main aspect of the present invention includes: a fixing part; a drive part placed on a lateral side of the fixing part and coupled to the fixing part; and a movable part configured to be driven by the drive part. A lower electrode, a piezoelectric layer, and an upper electrode are formed in order in an upper surface region of the fixing part and the drive part, and in a wiring region on the fixing part side of the upper surface region, a low dielectric layer containing at least one element forming the piezoelectric layer is formed on an upper surface of the piezoelectric layer.

In the drive element according to this aspect, since the low dielectric layer is formed on the upper surface of the piezoelectric layer in the wiring region, a voltage drop is caused by the low dielectric layer in the wiring region, so that the voltage applied to the piezoelectric layer in the wiring region can be reduced. Accordingly, unnecessary displacement and stress are suppressed in the wiring region. Thus, damage to the drive element (wiring region) can be avoided, and the reliability thereof can be increased. In addition, since the low dielectric layer contains at least one element forming the piezoelectric layer, the low dielectric layer and the piezoelectric layer are likely to cause interface mixing, so that the adhesion between the low dielectric layer and the piezoelectric layer can be enhanced. Accordingly, the low dielectric layer is inhibited from peeling off from the upper surface of the piezoelectric layer, and thus the reliability of the drive element can be increased.

The effects and the significance of the present invention will be further clarified by the description of the embodiments below. However, the embodiments below are merely examples for implementing the present invention. The present invention is not limited to the description of the embodiments below in any way.

### BRIEF DESCRIPTION OF THE DRAWINGS

FIG. 1 is a plan view schematically showing a configuration of a drive element according to Embodiment 1;

FIG. 2 is a diagram schematically showing a C1-C2 cross-section of FIG. 1 according to Embodiment 1;

FIG. 3A and FIG. 3B are each a diagram for describing a procedure for forming a lamination structure according to Embodiment 1;

FIG. 4A and FIG. 4B are each a diagram for describing the procedure for forming the lamination structure according to Embodiment 1;

FIG. 5A and FIG. 5B are each a diagram for describing the procedure for forming the lamination structure according to Embodiment 1;

FIG. 6A and FIG. 6B are each a diagram for describing a procedure for forming a lamination structure according to Embodiment 2;

FIG. 7A and FIG. 7B are each a diagram for describing a procedure for forming a lamination structure according to Embodiment 3;

FIG. 8 is a plan view schematically showing a configuration of a drive element according to Embodiment 4;

FIG. 9 is a plan view schematically showing a configuration of a drive element according to Embodiment 5;

FIG. 10 is a diagram schematically showing a C3-C4 cross-section of FIG. 9 according to Embodiment 5;

FIG. 11 is a block diagram showing configurations of the drive element and an external device connected to the drive element, according to Embodiment 5;

FIG. 12A is a diagram schematically showing the waveform of a reference voltage and the waveform of a detection signal causing an amplitude shift, according to Embodiment 5;

FIG. 12B is a diagram schematically showing the waveform of the reference voltage and the waveform of a detection signal causing a periodic shift, according to Embodiment 5;

FIG. 13A and FIG. 13B are respectively plan views schematically showing configurations of drive elements according to Modifications 1 and 2 of Embodiment 5; and

FIG. 14 is a plan view schematically showing a configuration of a drive element according to Embodiment 6.

It should be noted that the drawings are solely for description and do not limit the scope of the present invention by any degree.

### DETAILED DESCRIPTION

Hereinafter, embodiments of the present invention will be described with reference to the drawings. For convenience, in each drawing, X, Y, and Z axes that are orthogonal to each other are additionally shown. The Z-axis positive direction is the vertical upward direction.

### Embodiment 1

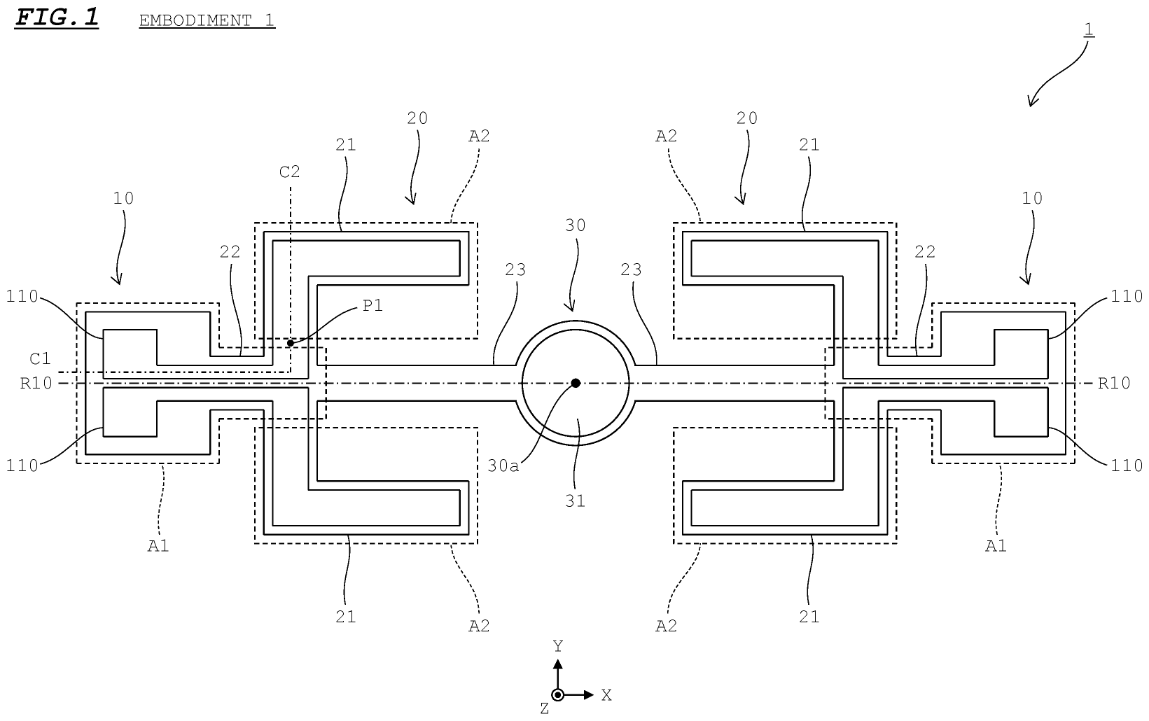

FIG. 1 is a plan view schematically showing a configuration of a drive element 1.

The drive element 1 includes a pair of fixing parts 10, a pair of drive parts 20, and a movable part 30. The drive element 1 is configured to be symmetrical in the X-axis direction and the Y-axis direction with a center 30a of the movable part 30 as a center. As the drive parts 20 are driven, the movable part 30 rotates about a rotation axis R10 which passes through the center 30a and extends in the X-axis direction.

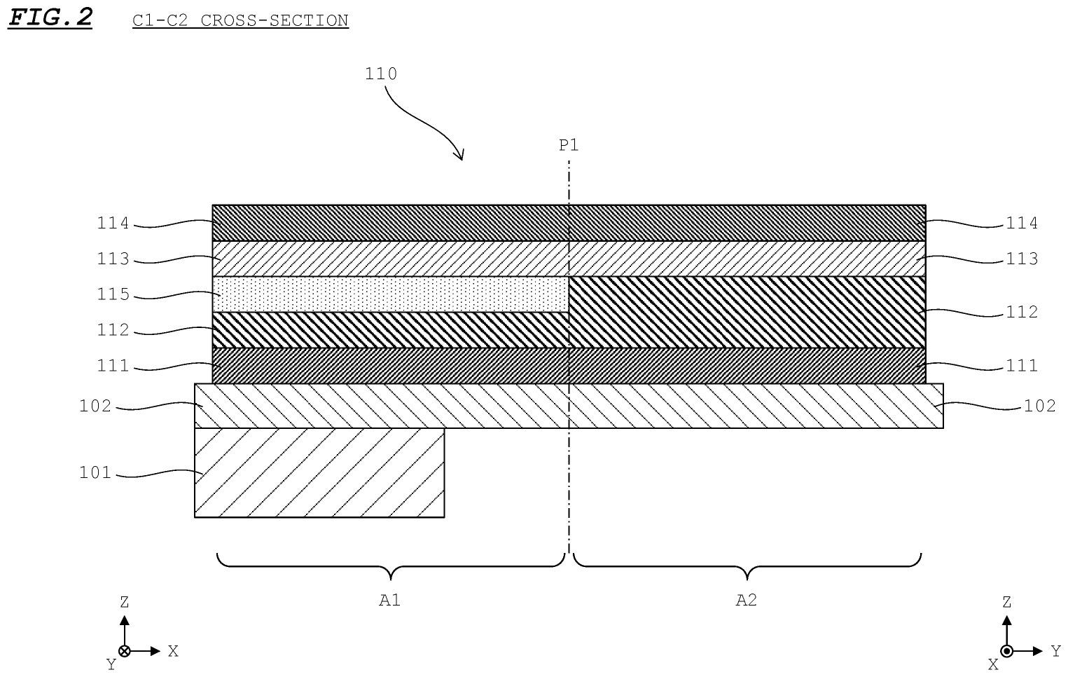

The pair of fixing parts 10 are aligned in the direction of the rotation axis R10. When the drive element 1 is installed, the surface on the Z-axis negative side of each fixing part 10 (the surface on the Z-axis negative side of a base 101 in FIG. 2) is installed on an installation location.

The pair of drive parts 20 each have a tuning fork shape. The pair of drive parts 20 are aligned in the direction of the rotation axis R10, and are placed on the lateral sides of the pair of fixing parts 10 and coupled to the fixing parts 10, respectively. Each drive part 20 includes a pair of vibration portions 21 and connection portions 22 and 23. The pair of vibration portions 21 are aligned in the Y-axis direction, and are configured to be line-symmetrical with respect to the rotation axis R10. The connection portions 22 and 23 extend along the rotation axis R10 and are coupled to each other. The fixing part 10 is connected to an outer end portion (end portion in a direction away from the center 30a) of the connection portion 22, and the movable part 30 is connected to an inner end portion (end portion in a direction toward the center 30a) of the connection portion 23.

A mirror 31 is provided on the surface on the Z-axis positive side of the movable part 30. The movable part 30 and the mirror 31 each have a circular shape centered at the center 30a.

A lamination structure 110 (see FIG. 2) is placed in each of upper surface regions of the fixing parts 10 and the drive parts 20. The lamination structure 110 is placed over wiring regions A1 and drive regions A2. Each wiring region A1 is a region including the fixing part 10, the connection portion 22, and the vicinity of the position where the connection portions 22 and 23 are connected. Each drive region A2 is a region, on the drive part 20, located outward of the position where the connection portions 22 and 23 are connected, in the Y-axis direction with respect to the rotation axis R10. Each wiring region A1 is a region for supplying a drive voltage to the drive regions A2, and each drive region A2 is a region driven by the supplied drive voltage. The configuration of the lamination structure 110 in each wiring region A1 and each drive region A2 will be described with reference to FIG. 2 later.

An end portion on the fixing part 10 side of the lamination structure 110 in the wiring region A1 is connected to an external power supply or the like. When the drive part 20 is driven, voltages having opposite phases are applied to two vibration portions 21 (two lamination structures 110), which are aligned in the Y-axis direction, such that the two vibration portions 21 vibrate in opposite directions in the Z-axis direction. In addition, voltages having the same phase are applied to two vibration portions 21 (two lamination structures 110), which are aligned in the X-axis direction, such that the two vibration portions 21 vibrate in the same direction in the Z-axis direction. Accordingly, the movable part 30 and the mirror 31 rotate about the rotation axis R10, so that the direction of light incident on the mirror 31 is changed in accordance with the rotation angle of the mirror 31.

FIG. 2 is a diagram schematically showing a C1-C2 cross-section of FIG. 1.

When the C1-C2 cross-section is viewed in the Z-axis direction, the cross-section is bent by 90° near the position where the connection portions 22 and 23 are connected, as shown in FIG. 1. In FIG. 2, the lamination structure 110 is illustrated such that the cross-section bent by 90° as described above (a cross-section parallel to the X-Z plane and a cross-section parallel to the Y-Z plane) can be seen on the same plane. In FIG. 1 and FIG. 2, a position P1 indicating the boundary between the wiring region A1 and the drive region A2 is shown in the C1-C2 cross-section. In FIG. 2, X, Y, and Z axes indicating coordinates in the cross-section parallel to the X-Z plane in the C1-C2 cross-section, and X, Y, and Z axes indicating coordinates in the cross-section parallel to the Y-Z plane in the C1-C2 cross-section are also shown.

In the wiring region A1, the base 101 is placed in a range corresponding to the fixing part 10 shown in FIG. 1. On the upper surface of the base 101, a device layer 102 is placed so as to extend over the wiring region A1 and the drive region A2. The device layer 102 is placed in a range corresponding to the fixing parts 10, the drive parts 20, and the movable part 30 shown in FIG. 1. The base 101 is composed of a BOX layer (SiO₂) and a handle layer (Si) of a SOI substrate. The device layer 102 is composed of a device layer (Si) of the SOI substrate. During the formation of the base 101 and the device layer 102, the SOI substrate including the device layer, the BOX layer, and the handle layer is formed in a shape in a plan view in FIG. 1. Then, the BOX layer and the handle layer of the SOI substrate are removed such that the BOX layer and the handle layer of the SOI substrate remain only in the range corresponding to each fixing part 10. Accordingly, the bases 101 and the device layer 102 are formed.

The lamination structure 110 is placed on the upper surface of the device layer 102. In the entire lamination structure 110, a lower electrode 111, a piezoelectric layer 112, an upper electrode adhesion layer 113, and an upper electrode 114 are formed in this order in the Z-axis positive direction. In the wiring region A1 of the lamination structure 110, a low dielectric layer 115 is formed on the upper surface of the piezoelectric layer 112.

In Embodiment 1, the lower electrode 111 is made of platinum (Pt), the piezoelectric layer 112 is made of PZT (lead zirconate titanate: Pb(Zr, Ti)O₃), the upper electrode adhesion layer 113 is made of nickel (Ni), the upper electrode 114 is made of gold (Au), and the low dielectric layer 115 is made of PbTiOₓ and titanium dioxide (TiO₂).

As shown in FIG. 2, the piezoelectric layer 112 is placed between the lower electrode 111 and the upper electrode 114, and thus also serves as a dielectric body that insulates the lower electrode 111 and the upper electrode 114 from each other.

At each fixing part 10 (see FIG. 1), for example, when the lower electrode 111 on the fixing part 10 side is connected to a ground and a voltage is applied to the upper electrode 114 on the fixing part 10 side, the piezoelectric layer 112 in each drive region A2 vibrates. Accordingly, the drive parts 20 (see FIG. 1) are driven, and the movable part 30 and the mirror 31 (see FIG. 1) rotate about the rotation axis R10. However, in general, if the piezoelectric layer 112 is placed in each wiring region A1, unnecessary displacement and stress also occur in the wiring region A1, causing damage to the wiring region A1. On the other hand, in Embodiment 1, since the low dielectric layer 115 is provided in each wiring region A1, a voltage applied to the wiring region A1 can be reduced. Accordingly, damage to the wiring region A1 can be avoided, and the reliability of the drive element 1 can be increased.

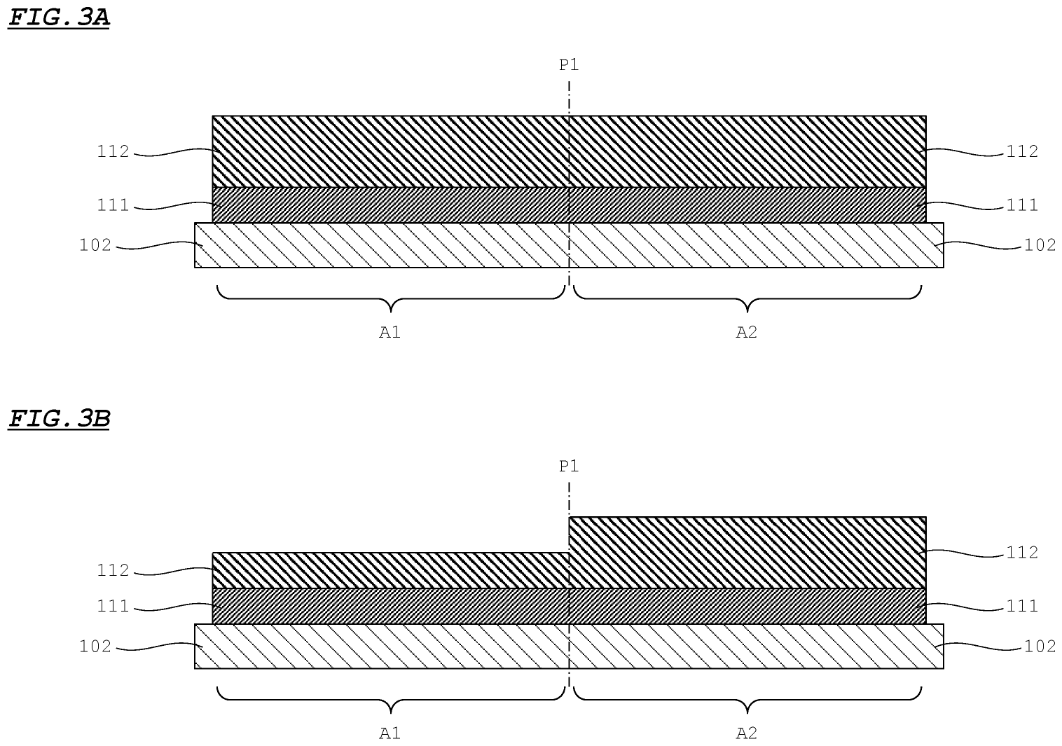

Next, a procedure for forming the lamination structure 110 will be described with reference to FIG. 3A to FIG. 5B. In FIG. 3A to FIG. 5B, for convenience, the base 101 is not shown.

As shown in FIG. 3A, the lower electrode 111 and the piezoelectric layer 112 are formed on the upper surface of the device layer 102 in this order.

Subsequently, as shown in FIG. 3B, an upper portion of the piezoelectric layer 112 corresponding to the wiring region A1 is removed by etching to a depth corresponding to the low dielectric layer 115 to be formed in the wiring region A1.

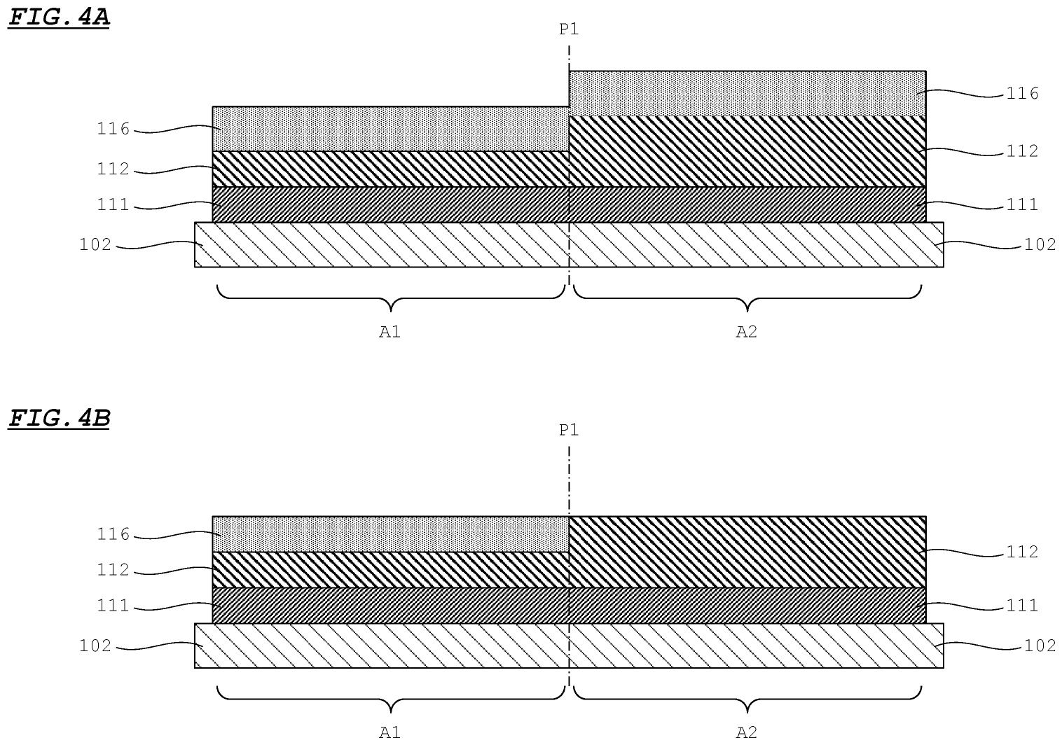

Subsequently, as shown in FIG. 4A, a metal layer 116 is formed on the entire upper surface of the piezoelectric layer 112 in FIG. 3B. The metal layer 116 is formed from a material that is denatured into the low dielectric layer 115 by heat treatment described later and that adheres closely to the piezoelectric layer 112. For example, the metal layer 116 is formed from titanium (Ti).

Subsequently, as shown in FIG. 4B, the metal layer 116 in FIG. 4A is removed such that the metal layer 116 remains only on the upper surface of the piezoelectric layer 112 in the wiring region A1. At this time, the metal layer 116 is removed such that the upper surface of the metal layer 116 in the wiring region A1 and the upper surface of the piezoelectric layer 112 in the drive region A2 are at substantially the same height.

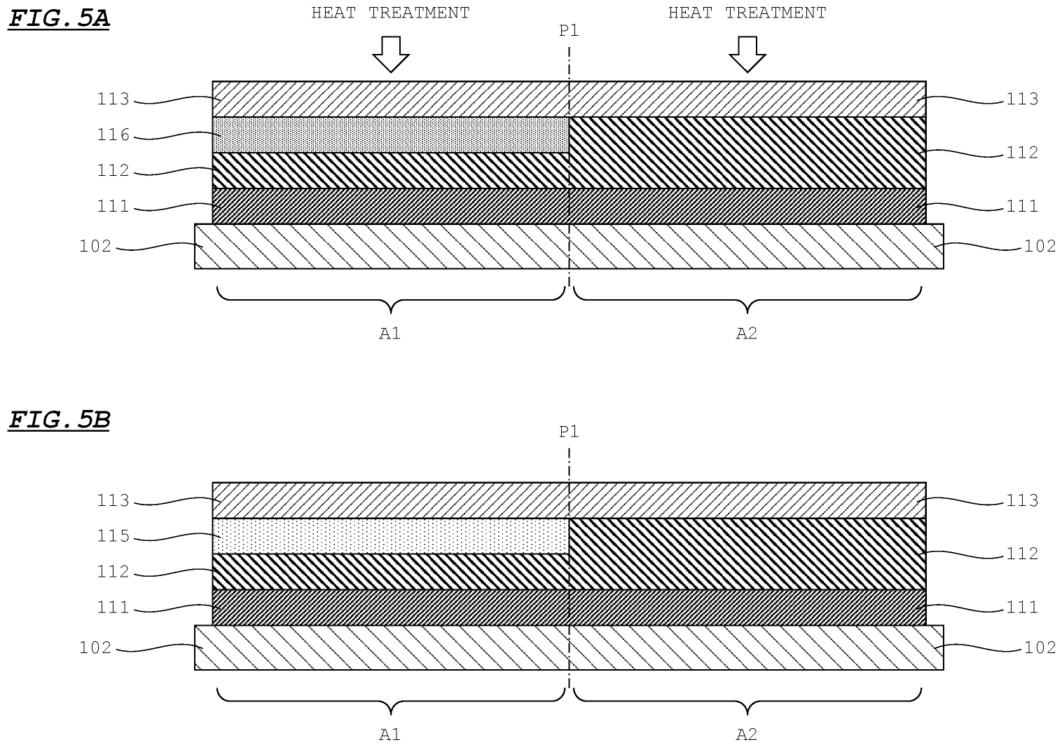

Subsequently, as shown in FIG. 5A, the upper electrode adhesion layer 113 is formed on the upper surface of the wiring region A1 and the upper surface of the drive region A2 in FIG. 4B. The upper electrode adhesion layer 113 is formed from a material that has high adhesion to the upper electrode 114. For example, the upper electrode adhesion layer 113 is formed from nickel (Ni). Then, heat is applied to the wiring region A1. Accordingly, the metal layer 116 is denatured into the low dielectric layer 115.

Specifically, a part of titanium forming the metal layer 116 changes to PbTiOₓ by thermally reacting with the piezoelectric layer 112. In addition, other titanium forming the metal layer 116 changes to titanium dioxide by combining with oxygen in the piezoelectric layer 112 and oxygen around the metal layer 116 due to heat. That is, when heat is applied to the metal layer 116, the metal layer 116 is changed to the low dielectric layer 115 containing a component of the piezoelectric layer 112. In other words, the metal layer 116 is changed to the low dielectric layer 115 containing at least one element forming the piezoelectric layer 112. In addition, the metal layer 116 in the state in FIG. 5A tends to change to PbTiOₓ or titanium dioxide the closer it is to the piezoelectric layer 112. In the step in FIG. 5B, heat that causes these reactions is applied to the wiring region A1.

Here, the metal layer 116 is formed from a metal that has a lower standard reaction Gibbs energy of oxide than the metal forming the upper electrode adhesion layer 113. When a gas constant is denoted by R, an absolute temperature is denoted by T, and an oxygen partial pressure is denoted by Pₒ₂, a standard reaction Gibbs energy ΔG of oxide is represented as ΔG=−RTlnPₒ₂. A metal material having low ΔG oxidizes at a low oxygen partial pressure (low temperature). For example, in a heat treatment atmosphere at 400° C., the metal (titanium) forming the metal layer 116 is oxidized into titanium dioxide at Pₒ₂ of 10⁻⁷ Pa or higher, and the metal (nickel) forming the upper electrode adhesion layer 113 is oxidized into nickel oxide (NiO) at Pₒ₂ of 10⁻¹ Pa or higher. Therefore, in thermal oxidation treatment, first, heat treatment is performed on the wiring region A1 such that Pₒ₂ is in an order of 10⁻³ to 10⁻⁶ Pa, and then heat treatment is performed with the oxygen partial pressure increased to 10⁻¹ Pa or higher, whereby the metal (titanium) forming the metal layer 116 is oxidized and denatured into the low dielectric layer 115, and then the metal (nickel) forming the upper electrode adhesion layer 113 and titanium which is the metal forming the low dielectric layer 115 are caused to form a covalent bond via oxygen. As a result, strong adhesion can be obtained between each layer.

Thus, as shown in FIG. 5B, the low dielectric layer 115 is formed on the upper surface of the piezoelectric layer 112 in the wiring region A1, and the upper electrode adhesion layer 113 is formed on the upper surface of the low dielectric layer 115 in the wiring region A1. Since the metal layer 116 is denatured into the low dielectric layer 115 by the heat treatment as described above and the low dielectric layer 115 and the piezoelectric layer 112 contain titanium as a common element, the low dielectric layer 115 and the piezoelectric layer 112 are likely to cause interface mixing, and accordingly, the adhesion between the piezoelectric layer 112 and the low dielectric layer 115 is enhanced.

When heat is applied to the wiring region A1, the metal (nickel) forming the upper electrode adhesion layer 113 in the wiring region A1 and the metal (titanium in Embodiment 1) forming the low dielectric layer 115 in the wiring region A1 are covalently bonded via an oxygen atom. Accordingly, in the wiring region A1, the upper electrode adhesion layer 113 and the low dielectric layer 115 adhere closely to each other. Similarly, heat is also applied to the drive region A2. Accordingly, the metal (nickel) forming the upper electrode adhesion layer 113 in the drive region A2 and the metal (titanium or lead) forming the piezoelectric layer 112 in the drive region A2 are covalently bonded via an oxygen atom. As a result, in the drive region A2, the upper electrode adhesion layer 113 and the piezoelectric layer 112 adhere closely to each other.

As shown in the state in FIG. 5A, the upper surface of the metal layer 116 in the wiring region A1 and the upper surface of the piezoelectric layer 112 in the drive region A2 are at substantially the same height, and thus, in the state shown in FIG. 5B as well, the upper surface of the low dielectric layer 115 in the wiring region A1 and the upper surface of the piezoelectric layer 112 in the drive region A2 are at substantially the same height. Accordingly, the upper surface and the lower surface of the upper electrode adhesion layer 113 in the wiring region A1 are at substantially the same height as the upper surface and the lower surface of the upper electrode adhesion layer 113 in the drive region A2, respectively.

Subsequently, the upper electrode 114 is formed on the upper surface of the upper electrode adhesion layer 113 in FIG. 5B. Thus, the lamination structure 110 shown in FIG. 2 is completed.

### Effects of Embodiment 1

According to Embodiment 1, the following effects are achieved.

In each wiring region A1 on the fixing part 10 side of the upper surface regions of the fixing parts 10 and the drive parts 20, the low dielectric layer 115 containing at least one element (component of the piezoelectric layer 112) forming the piezoelectric layer 112 is formed on the upper surface of the piezoelectric layer 112 as shown in FIG. 2.

In this configuration, since the low dielectric layer 115 is formed on the upper surface of the piezoelectric layer 112 in the wiring region A1, a voltage drop is caused by the low dielectric layer 115 in the wiring region A1, so that the voltage applied to the piezoelectric layer 112 in the wiring region A1 can be reduced. Accordingly, unnecessary displacement and stress are suppressed in the wiring region A1. Thus, damage to the wiring region A1 can be avoided, and the reliability of the drive element 1 can be increased. In addition, since the voltage to the piezoelectric layer 112 in the wiring region A1 can be reduced, the power consumption of the drive part 20 can be reduced.

Since the low dielectric layer 115 and the piezoelectric layer 112 contain the same component (titanium in Embodiment 1), the low dielectric layer 115 and the piezoelectric layer 112 are likely to cause interface mixing by heat treatment, so that the adhesion between the low dielectric layer 115 and the piezoelectric layer 112 can be enhanced. Accordingly, the low dielectric layer 115 is inhibited from peeling off from the upper surface of the piezoelectric layer 112, and thus the reliability of the drive element 1 can be increased.

The low dielectric layer 115 is formed by thermally reacting the piezoelectric layer 112 and the metal layer 116 which is provided on the piezoelectric layer 112. As described above, the thermal reaction refers to a reaction in which the titanium in the metal layer 116 is changed to PbTiOₓ or titanium dioxide by applying heat to the metal layer 116 in a state where the metal layer 116 is stacked on the piezoelectric layer 112. In this configuration, the low dielectric layer 115 can be easily formed. In addition, since the metal layer 116 is changed to the low dielectric layer 115 containing PbTiOₓ or titanium dioxide by the thermal reaction, the low dielectric layer 115 and the piezoelectric layer 112 contain titanium or lead as a common element, so that the low dielectric layer 115 and the piezoelectric layer 112 cause interface mixing. Accordingly, the low dielectric layer 115 is less likely to peel off from the upper surface of the piezoelectric layer 112.

The metal layer 116 is more likely to cause the thermal reaction with the piezoelectric layer 112 the closer it is to the piezoelectric layer 112. Therefore, the low dielectric layer 115 contains more of a component (e.g., an element such as titanium or lead) of the piezoelectric layer 112 the closer it is to the piezoelectric layer 112, and the low dielectric layer 115 and the piezoelectric layer 112 cause interface mixing with the component of the piezoelectric layer 112. Therefore, the interface between the low dielectric layer 115 and the piezoelectric layer 112 becomes indistinct, so that external stress can be dispersed. Accordingly, peeling due to external stress can be prevented.

The upper electrode adhesion layer 113 is placed on the upper surface of the low dielectric layer 115 in the wiring region A1 and the upper surface of the piezoelectric layer 112 in the drive region A2. In this configuration, in the wiring region A1, the metal atoms (nickel) of the upper electrode adhesion layer 113 and the metal atoms (titanium in Embodiment 1) of the low dielectric layer 115 are covalently bonded via oxygen atoms by heat treatment, and thus the upper electrode adhesion layer 113 and the low dielectric layer 115 can be caused to adhere closely to each other. In addition, in the drive region A2, the metal atoms (nickel) of the upper electrode adhesion layer 113 and the metal atoms (titanium in Embodiment 1) of the piezoelectric layer 112 are covalently bonded via oxygen atoms by heat treatment, and thus the upper electrode adhesion layer 113 and the piezoelectric layer 112 can be caused to adhere closely to each other. Therefore, peeling of the upper electrode adhesion layer 113 can be prevented.

Since the upper electrode adhesion layer 113 is placed between the upper electrode 114 and the piezoelectric layer 112, the adhesion strength of the upper surface of the piezoelectric layer 112 can be increased as compared to the case where the upper electrode adhesion layer 113 is not placed. Therefore, peeling of the upper electrode 114 by stress or external force when the piezoelectric layer 112 is driven can be suppressed, so that the reliability of the drive element 1 can be increased.

The metal (titanium) contained in the low dielectric layer 115 has a lower standard reaction Gibbs energy of oxide than the metal (nickel) contained in the upper electrode adhesion layer 113. Thus, the material for forming each layer is selected such that the standard reaction Gibbs energy of oxide of the low dielectric layer 115 is lower than that of the upper electrode adhesion layer 113, and the oxygen partial pressure is adjusted during oxidation heat treatment as described above. Accordingly, during heat treatment of the metal layer 116 (titanium), the metal (titanium) of the low dielectric layer 115 can be made into a dielectric body while oxidation of the upper electrode adhesion layer 113 (nickel) is suppressed, and the adhesion between the upper electrode adhesion layer 113 and the low dielectric layer 115 can also be improved by the subsequent heat treatment.

The upper surface of the low dielectric layer 115 in the wiring region A1 and the upper surface of the piezoelectric layer 112 in the drive region A2 are at substantially the same height. In this configuration, the upper electrode 114 in the wiring region A1 and the upper electrode 114 in the drive region A2 are connected at substantially the same height, and therefore, as compared to the case where there is a step at the boundary between the wiring region A1 and the drive region A2, stress can be inhibited from being applied to this boundary when the drive element 1 is driven. Accordingly, the upper electrode 114 which extends over the wiring region A1 and the drive region A2 can be prevented from being broken. In addition, in the case where there is a step between the upper surface of the low dielectric layer 115 in the wiring region A1 and the upper surface of the piezoelectric layer 112 in the drive region A2, the thicknesses of the upper electrode adhesion layer 113 and the upper electrode 114 near the boundary at the step are likely to vary with respect to the thicknesses of the other portions. On the other hand, in Embodiment 1 described above, such a step is not formed, and thus the thicknesses of the upper electrode adhesion layer 113 and the upper electrode 114 are substantially uniform in the entire range of the wiring region A1 and the drive region A2. Therefore, the resistance of the upper electrode 114 can be set to be substantially uniform. Accordingly, the resistance of the upper electrode 114 can be stabilized.

In the case where the upper surface of the upper electrode 114 in the wiring region A1 and the upper surface of the upper electrode 114 in the drive region A2 are connected at different heights, the upper electrode 114 which extends over the wiring region A1 and the drive region A2 is likely to be broken. To avoid this, it is necessary to increase the thickness of the upper electrode 114. On the other hand, in the configuration of Embodiment 1, since the upper electrode 114 in the wiring region A1 and the upper electrode 114 in the drive region A2 are connected at substantially the same height, breaking of the upper electrode 114 can be inhibited, so that the thickness of the upper electrode 114 can be decreased.

### Embodiment 2

In Embodiment 1, the low dielectric layer 115 is formed by thermally reacting the metal layer 116. However, in Embodiment 2, the low dielectric layer 115 is formed by performing ion implantation into the piezoelectric layer 112. Hereinafter, a procedure for forming the low dielectric layer 115 will be described.

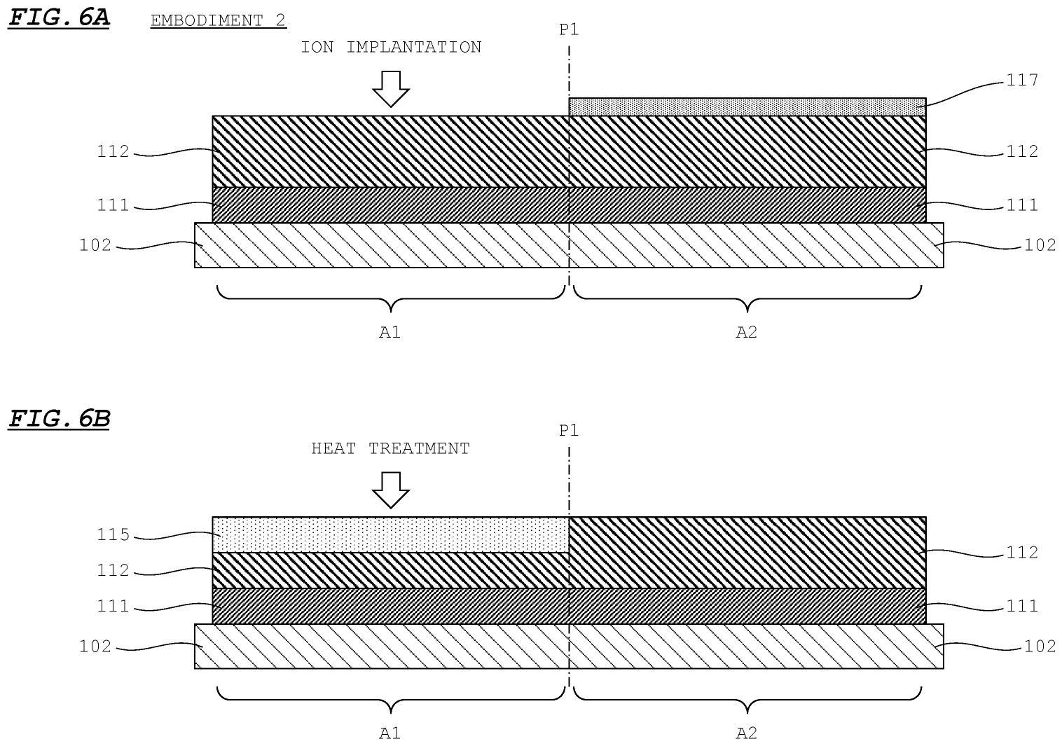

As shown in FIG. 6A, a resist layer 117 is formed on the upper surface of the piezoelectric layer 112 in the drive region A2, of the piezoelectric layer 112 in FIG. 3A. In this state, ion implantation is performed on the piezoelectric layer 112 exposed upward in the wiring region A1. The ions to be implanted are atoms of the B site of a perovskite structure, and include, for example, at least one of titanium (Ti), zirconium (Zr), niobium (Nb), zinc (Zn), and magnesium (Mg). Accordingly, deficiency is caused in the perovskite structure of PZT (Pb(Zr, Ti)O₃) forming the piezoelectric layer 112.

When the ion implantation on the piezoelectric layer 112 in the wiring region A1 is completed from the state in FIG. 6A, the resist layer 117 placed on the upper surface of the piezoelectric layer 112 in the drive region A2 is removed as shown in FIG. 6B. Then, after resist peeling, heat is applied to the piezoelectric layer 112 in the wiring region A1. By performing heat treatment on the piezoelectric layer 112 in which deficiency has been caused in the perovskite structure, a pyrochlore structure is formed in this portion.

The pyrochlore structure has a lower relative permittivity than the perovskite structure and has no piezoelectricity. Thus, the piezoelectric layer 112 in the wiring region A1 is changed to the low dielectric layer 115 having a low relative permittivity. The composition ratio of the pyrochlore structure is, for example, A₂B₂O₇. Since the low dielectric layer 115 is obtained by denaturing the piezoelectric layer 112 through the ion implantation and the heat treatment, the low dielectric layer 115 still contains a component (atom such as titanium or lead) in common with the piezoelectric layer 112 even after the change to the pyrochlore structure.

In this case as well, as in Embodiment 1, the upper surface of the low dielectric layer 115 in the wiring region A1 and the upper surface of the piezoelectric layer 112 in the drive region A2 are at substantially the same height. Subsequently, the upper electrode adhesion layer 113 made of nickel is formed on the entire upper surface of the wiring region A1 and the drive region A2, heat is applied thereto, and the upper electrode 114 is formed on the upper surface of the upper electrode adhesion layer 113. Thus, the lamination structure 110 shown in FIG. 2 is completed.

### Effects of Embodiment 2

According to Embodiment 2, the following effects are achieved.

In Embodiment 2 as well, as in Embodiment 1, in each wiring region A1, the low dielectric layer 115 containing at least one element (component of the piezoelectric layer 112) forming the piezoelectric layer 112 is formed on the upper surface of the piezoelectric layer 112 as shown in FIG. 2. Since the low dielectric layer 115 of Embodiment 2 is formed by performing ion implantation and heat treatment on a part of the piezoelectric layer 112, the low dielectric layer 115 is a dielectric body that has a lower relative permittivity than the original piezoelectric layer 112 and that has no piezoelectricity. Therefore, as in Embodiment 1, a voltage drop is caused by the low dielectric layer 115 in the wiring region A1, and thus the voltage applied to the piezoelectric layer 112 in the wiring region A1 can be reduced. Accordingly, unnecessary displacement and stress are suppressed in the wiring region A1. Thus, damage to the wiring region A1 can be avoided, and the reliability of the drive element 1 can be increased.

In Embodiment 2 as well, the low dielectric layer 115 and the piezoelectric layer 112 contain the same component (titanium or lead in Embodiment 2). Thus, the low dielectric layer 115 and the piezoelectric layer 112 are likely to cause interface mixing, so that the adhesion between the low dielectric layer 115 and the piezoelectric layer 112 can be enhanced.

The low dielectric layer 115 is formed by performing ion implantation and heat treatment on the piezoelectric layer 112. By the ion implantation, deficiency can be caused in the perovskite structure forming the piezoelectric layer 112. In addition, by the heat treatment, oxygen is given to the perovskite structure in which deficiency has been caused, whereby a pyrochlore structure can be formed. Accordingly, the piezoelectric layer 112 on which the ion implantation and the heat treatment have been performed can be changed to the low dielectric layer 115.

The ions to be implanted into the piezoelectric layer 112 during the formation of the low dielectric layer 115 are atoms of the B site of the perovskite structure, and include, for example, at least one of titanium (Ti), zirconium (Zr), niobium (Nb), zinc (Zn), and magnesium (Mg). Accordingly, excess A-site deficiency can be caused in the perovskite structure, of the piezoelectric layer 112, in which deficiency has been caused, and thus a pyrochlore structure can be easily formed by the subsequent heat treatment.

Since the ion implantation is performed on the piezoelectric layer 112 exposed upward in the wiring region A1, the closer to the upper surface of the piezoelectric layer 112, the more likely it is for the piezoelectric layer 112 to be affected by the ion implantation and the heat treatment, resulting in a pyrochlore structure. Therefore, the low dielectric layer 115 contains more of the structure of the piezoelectric layer 112 (perovskite structure) as advancing downward from the upper surface of the low dielectric layer 115 (the closer it is to the piezoelectric layer 112 located below the low dielectric layer 115). Therefore, the interface between the low dielectric layer 115 and the piezoelectric layer 112 becomes indistinct, so that external stress applied to the interface can be dispersed. Accordingly, peeling due to external stress can be prevented.

### Embodiment 3

In Embodiment 1, the low dielectric layer 115 is composed of a single layer. However, in Embodiment 3, the low dielectric layer 115 is composed of two layers. Hereinafter, a procedure for forming the low dielectric layer 115 will be described.

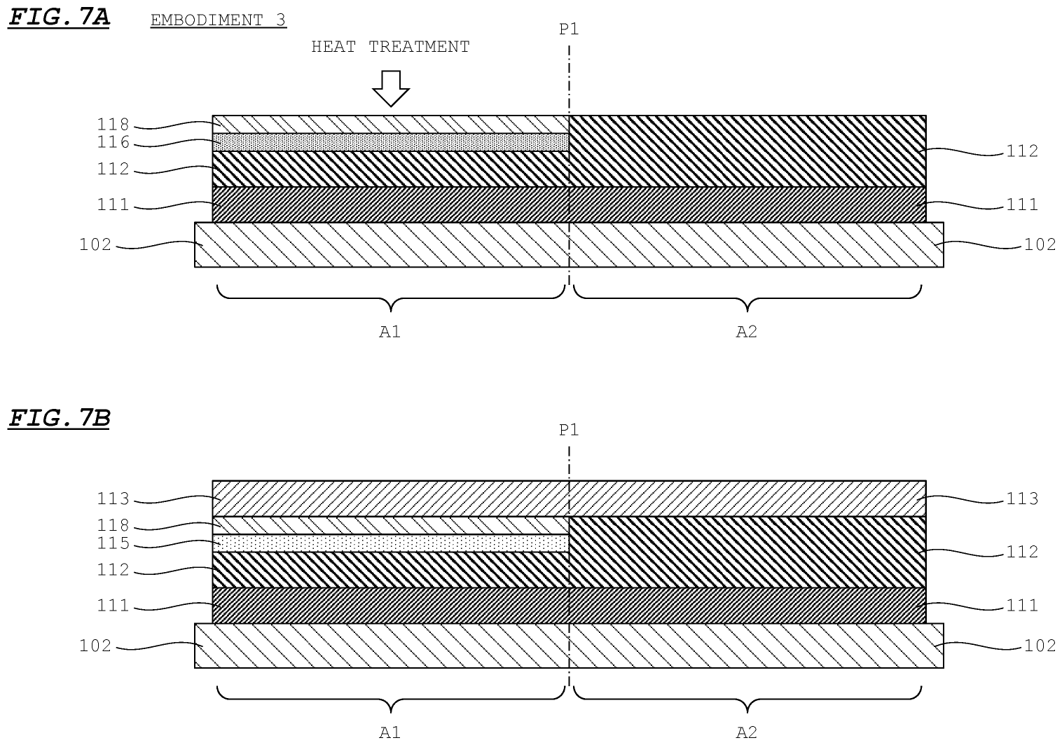

A metal layer 116 which is the same as in Embodiment 1 and a low dielectric layer 118 are stacked in this order on the piezoelectric layer 112 in FIG. 3B, and the metal layer 116 and the low dielectric layer 118 stacked in the region other than the wiring region A1 are removed. Accordingly, as shown in FIG. 7A, the metal layer 116 and the low dielectric layer 118 are stacked only on the upper surface of the piezoelectric layer 112 in the wiring region A1. At this time, the upper surface of the low dielectric layer 118 is set at substantially the same height as the upper surface of the piezoelectric layer 112 in the drive region A2. The low dielectric layer 118 is formed from alumina (Al₂O₃), silicon dioxide (SiO₂), silicon nitride (Si₃N₄), silicon oxynitride (SiON), or the like.

Subsequently, heat is applied to the metal layer 116 and the low dielectric layer 118 in the wiring region A1. Accordingly, as shown in FIG. 7B, the metal layer 116 is changed to the low dielectric layer 115 as in Embodiment 1. At this time, since the low dielectric layer 118 is formed in an oxidized or nitrided state, the composition of the low dielectric layer 118 is not substantially changed by heat. In addition, the upper surface of the low dielectric layer 118 in the wiring region A1 and the upper surface of the piezoelectric layer 112 in the drive region A2 are at substantially the same height. Then, as shown in FIG. 7B, as in Embodiment 1, the upper electrode adhesion layer 113 made of nickel is formed on the entire upper surface of the wiring region A1 and the drive region A2, and heat is applied thereto. Then, the upper electrode 114 is formed on the upper surface of the upper electrode adhesion layer 113. Thus, the lamination structure 110 shown in FIG. 2 is completed.

### Effects of Embodiment 3

In Embodiment 3 as well, as in Embodiment 1, in each wiring region A1, the low dielectric layer 115 containing at least one element (component of the piezoelectric layer 112) forming the piezoelectric layer 112 is formed on the upper surface of the piezoelectric layer 112 as shown in FIG. 2. Therefore, as in Embodiment 1, a voltage drop is caused by the low dielectric layer 115 in the wiring region A1, and thus the voltage applied to the piezoelectric layer 112 in the wiring region A1 can be reduced. Accordingly, unnecessary displacement or stress is suppressed in the wiring region A1. Thus, damage to the wiring region A1 can be avoided, and the reliability of the drive element 1 can be increased.

The low dielectric layer in the wiring region A1 is multilayered. That is, in the wiring region A1, the low dielectric layers 115 and 118 are placed so as to be stacked between the piezoelectric layer 112 and the upper electrode adhesion layer 113. When the low dielectric layer 118 is formed from the above material, the relative permittivity of the low dielectric layer 118 can be further decreased as compared to the low dielectric layer 115. Accordingly, the voltage applied to the piezoelectric layer 112 in the wiring region A1 can be further reduced.

In the piezoelectric layer 112 and the low dielectric layer 115, as in Embodiment 1, the same component causes interface mixing of the low dielectric layer 115 and the piezoelectric layer 112, thereby allowing the adhesion between the piezoelectric layer 112 and the low dielectric layer 115 to be enhanced. In addition, in the case where the low dielectric layer 118 is formed from alumina, silicon dioxide, or silicon oxynitride, aluminum atoms or silicon atoms are covalently bonded to metal atoms (titanium or lead) of the low dielectric layer 115 via oxygen atoms or nitrogen atoms, thereby allowing the low dielectric layers 115 and 118 to adhere closely to each other.

### Embodiment 4

In Embodiment 1, the pair of drive parts 20 each have a tuning fork shape. However, in Embodiment 4, the pair of drive parts 20 each have a meander shape.

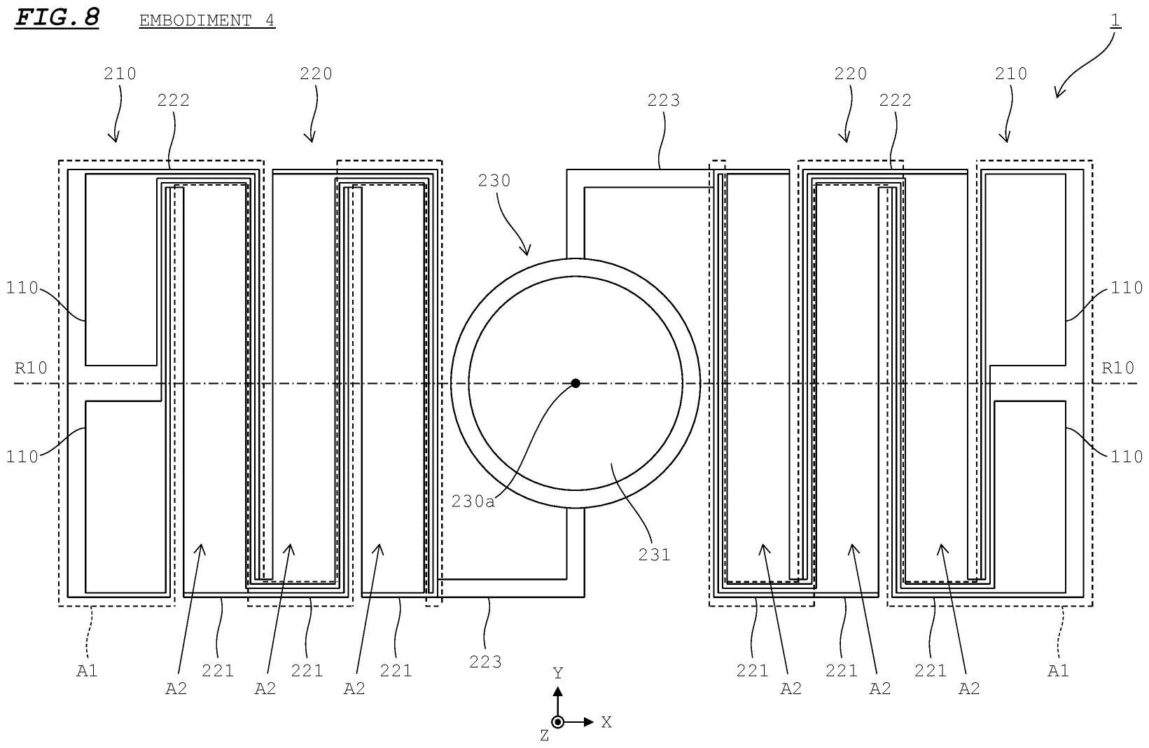

FIG. 8 is a plan view schematically showing a configuration of a drive element 1 according to Embodiment 4.

The drive element 1 includes a pair of fixing parts 210, a pair of drive parts 220, and a movable part 230. The drive element 1 is configured so as to be point-symmetrical with a center 230a of the movable part 230 as a center. As the drive parts 220 are driven, the movable part 230 rotates about a rotation axis R10 which passes through the center 230a and extends in the X-axis direction.

The pair of fixing parts 210 are aligned in the direction of the rotation axis R10. When the drive element 1 is installed, the surface on the Z-axis negative side of each fixing part 210 (the surface on the Z-axis negative side of the base 101 in FIG. 2) is installed on an installation location.

The pair of drive parts 220 each have a meander shape. The pair of drive parts 220 are aligned in the direction of the rotation axis R10, and are placed on the lateral sides of the pair of fixing parts 210 and coupled to the fixing parts 210. Each drive part 220 includes a plurality of vibration portions 221, a plurality of connection portions 222, and a connection portion 223. The plurality of vibration portions 221 are shaped so as to extend in the Y-axis direction, and are aligned so as to be spaced apart from each other in the X-axis direction. Two adjacent vibration portions 221 are connected at end portions thereof in the Y-axis direction by a connection portion 222 extending in the X-axis direction. An end portion in the Y-axis direction of the innermost vibration portion 221 is connected to an outer end portion (end portion in a direction away from the center 230a) of the connection portion 223, and the movable part 230 is connected to an inner end portion (end portion close to the center 230a) of the connection portion 223.

A mirror 231 is provided on the surface on the Z-axis positive side of the movable part 230. The movable part 230 and the mirror 231 have the same configurations as the movable part 30 and the mirror 31 of Embodiment 1.

A lamination structure 110 which is the same as in any of Embodiments 1 to 3 is placed in each of upper surface regions of the fixing parts 210 and the drive parts 220. Out of two lamination structures 110 aligned in the Y-axis direction, one lamination structure 110 is formed such that the area thereof is larger on the vibration portions 221 (first vibration portion group) placed at every other position, and the other lamination structure 110 is formed such that the area thereof is larger on the vibration portions 221 (second vibration portion group) on which the area of the one lamination structure 110 is smaller. An end portion on the fixing part 210 side of the lamination structure 110 is connected to an external power supply or the like. When each drive part 220 is driven, voltages having opposite phases are applied to the first vibration portion group and the second vibration portion group (two lamination structures 110) such that the first vibration portion group and the second vibration portion group vibrate in opposite directions in the Z-axis direction. Accordingly, the movable part 230 and the mirror 231 rotate about the rotation axis R10, so that the direction of light incident on the mirror 231 is changed in accordance with the rotation angle of the mirror 231.

In Embodiment 4, the fixing parts 210, the connection portions 222, and portions, of the vibration portions 221, in which the area of the lamination structure 110 is smaller are wiring regions A1. The portions, of the vibration portions 221, in which the area of the lamination structure 110 is larger are drive regions A2.

In Embodiment 4 as well, the lamination structure 110 is placed over the wiring regions A1 and the drive regions A2. In addition, a cross-section obtained when cutting from the position of the fixing part 210 in the wiring region A1 to the position of the drive part 220 in the drive region A2 along a cross-section parallel to the X-Z plane and a cross-section parallel to the Y-Z plane is the same as in FIG. 2. That is, in Embodiment 4 as well, the configuration of the lamination structure 110 in the wiring region A1 and the configuration of the lamination structure 110 in the drive region A2 are the same as in Embodiment 1, and the configuration of the lamination structure 110 extending over the wiring region A1 and the drive region A2 is also the same as in Embodiment 1. Therefore, in Embodiment 4, the same effects as those of Embodiment 1 are achieved.

### Embodiment 5

In Embodiment 5, a configuration for detecting drive of each drive part 20 is further added as compared to Embodiments 1 to 3.

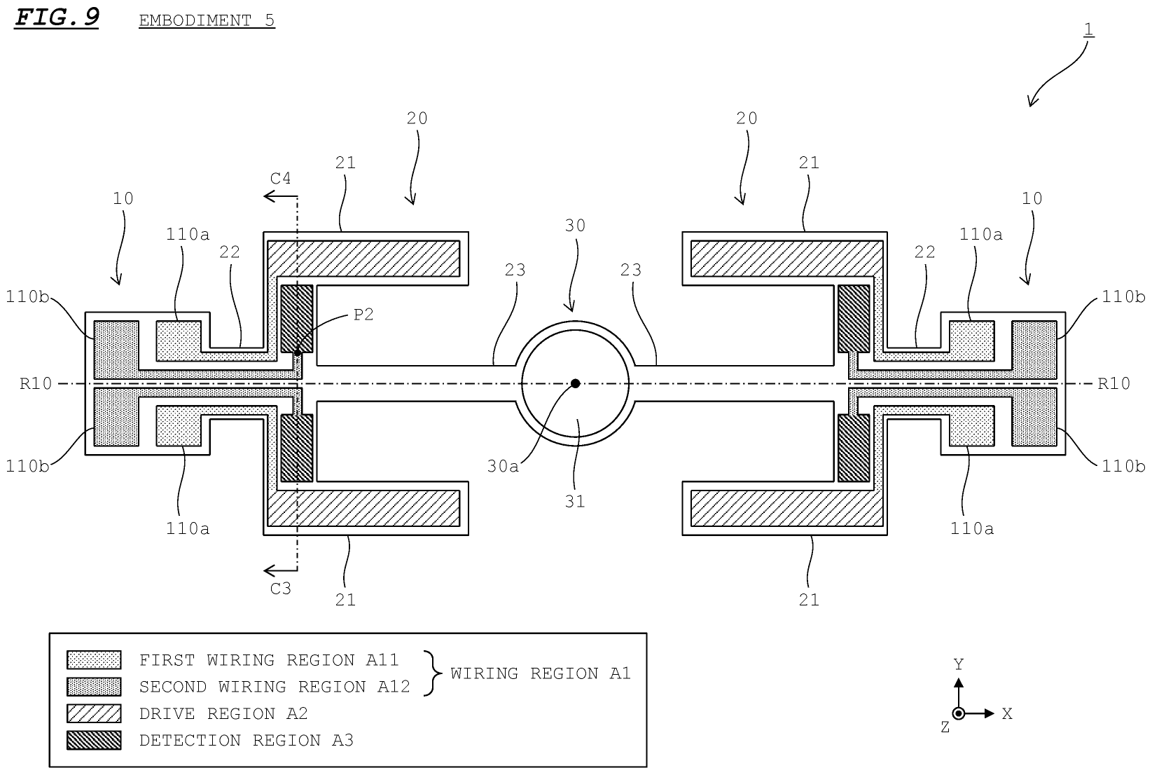

FIG. 9 is a plan view schematically showing a configuration of a drive element 1 according to Embodiment 5. In FIG. 9, for convenience, each region is marked with hatching or the like such that first wiring regions A11, second wiring regions A12, drive regions A2, and detection regions A3 can be distinguished from each other.

In Embodiment 5, the upper surface region of each fixing part 10 and each drive part 20 is divided into the first wiring regions A11, the second wiring regions A12, the drive regions A2, and the detection regions A3. Each drive region A2 is a region for driving the vibration portion 21. Each detection region A3 is a region for detecting displacement of the drive region A2. A pair of the drive region A2 and the detection region A3 placed on one vibration portion 21 drives the vibration portion 21 and detects displacement of the vibration portion 21.

Each drive region A2 is a region that is placed on a portion, of the vibration portion 21, extending in the X-axis direction and that has a rectangular shape in a plan view. Each detection region A3 is a region that is placed on a portion, of the vibration portion 21, extending in the Y-axis direction and that has a rectangular shape in a plan view.

Each wiring region A1 is divided into the first wiring region A11 and the second wiring region A12. The first wiring region A11 extends from the drive region A2 via the connection portion 22 to the fixing part 10. The second wiring region A12 extends from the detection region A3 via the connection portion 22 to the fixing part 10.

A lamination structure 110a formed in a region composed of the drive region A2 and the first wiring region A11 is the same as the lamination structure 110 of any of Embodiments 1 to 3 described above. The low dielectric layer 115 (or the low dielectric layers 115 and 118) is placed in the first wiring region A11, but is not placed in the drive region A2. A lamination structure 110b formed in a region composed of the detection region A3 and the second wiring region A12 is the same as the lamination structure 110 of any of Embodiments 1 to 3 described above. The low dielectric layer 115 (or the low dielectric layers 115 and 118) is placed in the second wiring region A12, but is not placed in the detection region A3. The lamination structures 110a and 110b are formed in the same method as the formation method shown in any of Embodiments 1 to 3 described above.

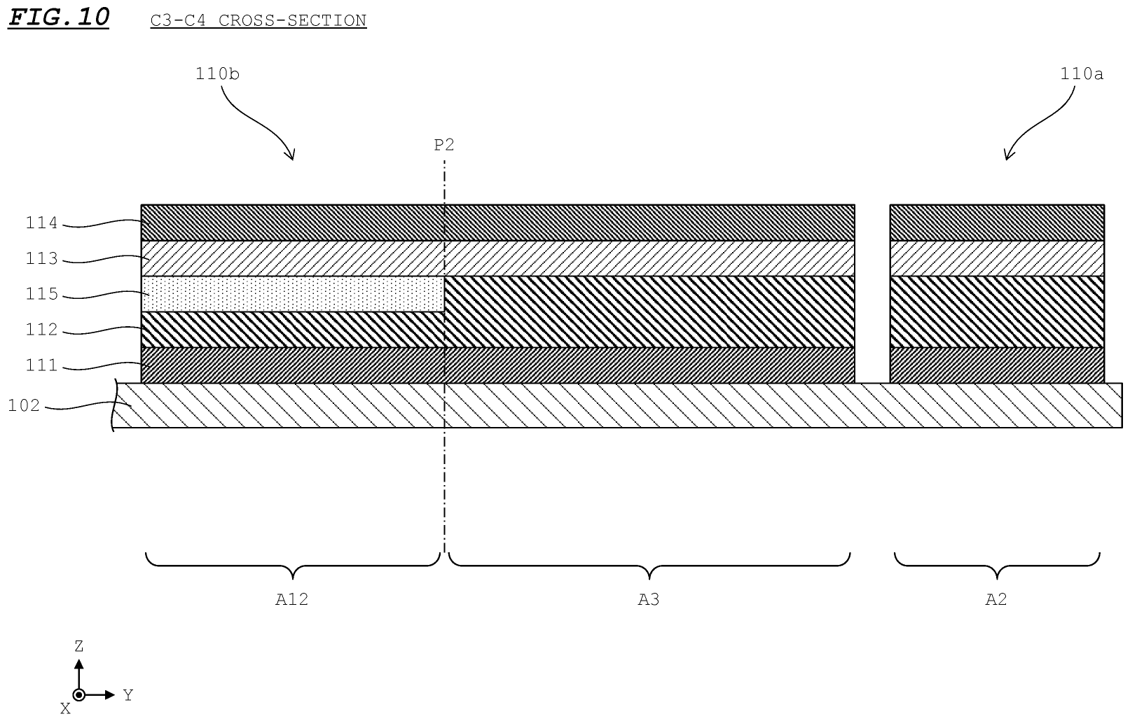

FIG. 10 is a diagram schematically showing a C3-C4 cross-section of FIG. 9.

For convenience, FIG. 10 shows a cross-section located on the Y-axis positive side of the rotation axis R10, of the C3-C4 cross-section. In addition, in FIG. 10, a position P2 indicating the boundary between the second wiring region A12 and the detection region A3 is shown in the C3-C4 cross-section. FIG. 10 shows a cross-section when the lamination structures 110a and 110b are formed as in any of Embodiments 1 and 2.

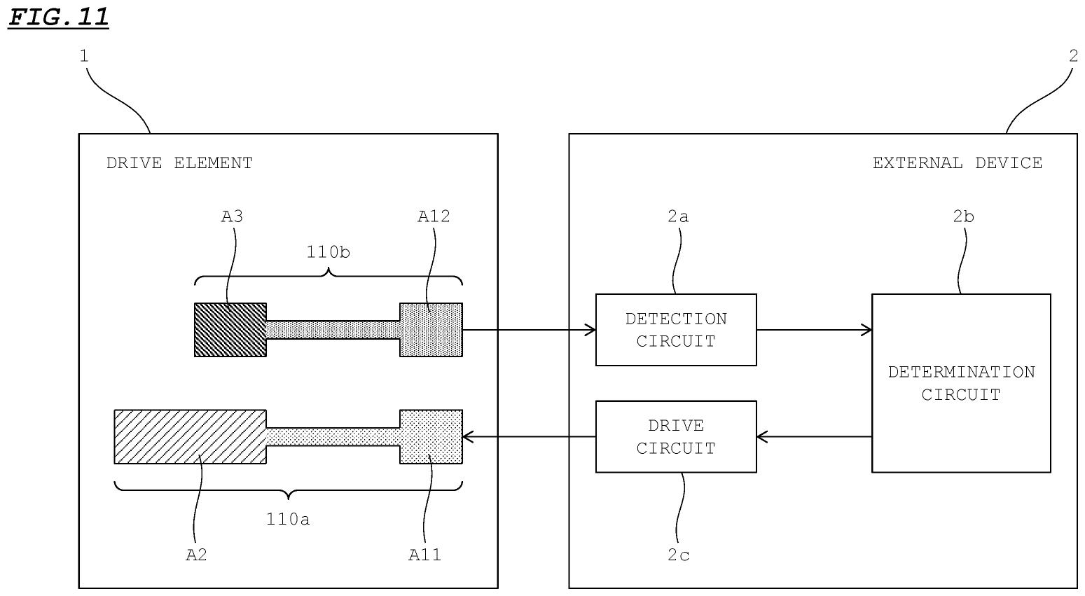

FIG. 11 is a block diagram showing configurations of the drive element 1 and an external device 2 connected to the drive element 1.

For convenience, FIG. 11 shows a pair of the drive region A2 and the detection region A3 placed on one vibration portion 21, and the first wiring region A11 and the second wiring region A12 connected thereto. In the external device 2, a circuitry shown in FIG. 11 is provided for each vibration portion 21.

The external device 2 includes a detection circuit 2a, a determination circuit 2b, and a drive circuit 2c. The detection circuit 2a is connected to the second wiring region A12, and the drive circuit 2c is connected to the first wiring region A11. The drive circuit 2c applies a sinusoidal drive voltage to the piezoelectric layer 112 in the drive region A2 via the first wiring region A11 to vibrate the vibration portion 21. When the vibration portion 21 vibrates, the electric charge generated in the lamination structure 110b in the detection region A3 is changed by the piezoelectric effect (d31) of the piezoelectric layer 112 of the vibration portion 21. The detection circuit 2a converts the electric charge in the detection region A3 that changes in response to the vibration of the vibration portion 21, into a voltage signal, and outputs a detection signal reflecting the change in electric charge, to the determination circuit 2b.

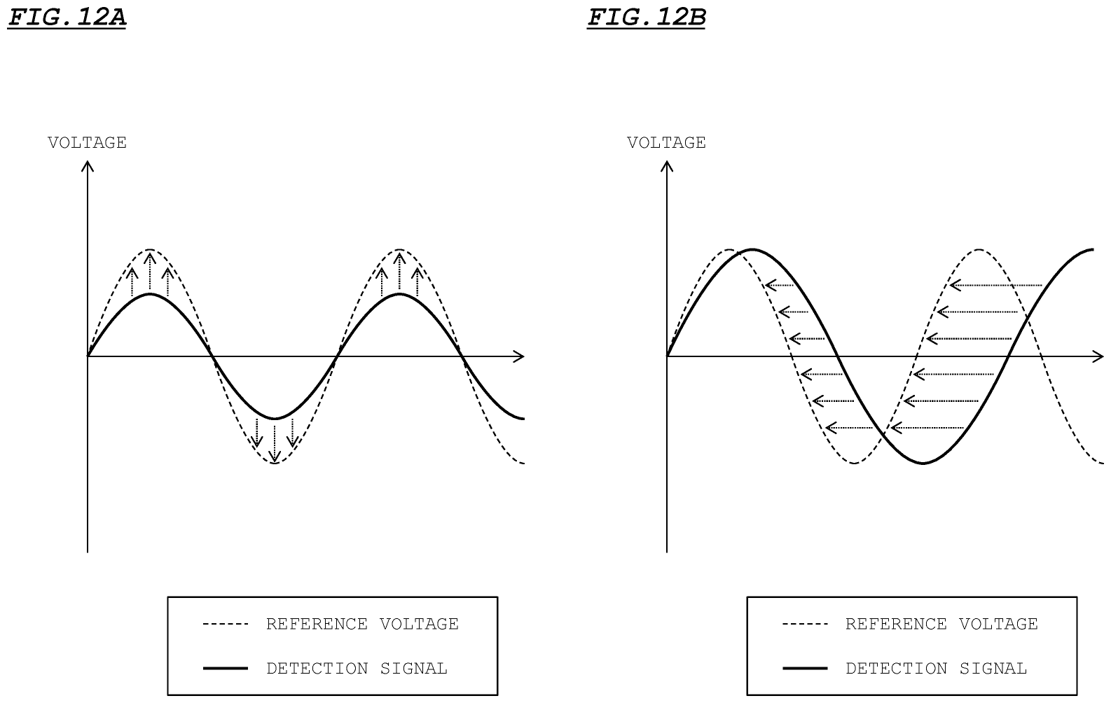

The determination circuit 2b determines whether or not the detection signal inputted from the detection circuit 2a matches the waveform of a reference signal. The waveform of the reference signal is an ideal waveform of a detection signal outputted from the detection circuit 2a when the movable part 30 vibrates at a target frequency and amplitude. The determination circuit 2b outputs a control signal to the drive circuit 2c such that the amplitude of the detection signal outputted from the detection circuit 2a matches the amplitude of the reference voltage as shown in FIG. 12A and the period of the detection signal outputted from the detection circuit 2a matches the period of the reference voltage as shown in FIG. 12B. The drive circuit 2c corrects the drive voltage to be applied to the piezoelectric layer 112 of the drive region A2, on the basis of the control signal outputted from the determination circuit 2b, and applies the corrected drive voltage to the piezoelectric layer 112 of the drive region A2.

This control allows the drive part 20 to vibrate at an appropriate vibration amplitude even when the piezoelectric characteristics of the piezoelectric layer 112 change due to degradation or temperature characteristics. In addition, this control allows the drive part 20 to vibrate at an appropriate frequency even when the device layer 102 included in the drive element 1 is fatigued or even when the resonance frequency of the drive element 1 changes due to temperature change.

Here, when the capacitance of the detection region A3 is denoted by Cd, the capacitance of the second wiring region A12 is denoted by Cw, and a change in electric charge caused in response to the vibration of the vibration portion 21 is denoted by ΔC, an SN ratio of detection accuracy of the detection circuit 2a can be represented as ΔC/(Cd+Cw). Therefore, the detection accuracy of the detection circuit 2a can be increased by decreasing the capacitances Cd and Cw.

However, when the capacitance Cd of the detection region A3 is decreased, the amount of change ΔC in electric charge also decreases. On the other hand, even when the capacitance Cw of the second wiring region A12 is decreased, since a wiring region, on the fixing part 10, in which a piezoelectric effect due to vibration does not occur is included, the amount of change ΔC in electric charge does not decrease much. In Embodiment 5, since the low dielectric layer 115 (or the low dielectric layers 115 and 118) is placed in the second wiring region A12, only the capacitance Cw of the second wiring region A12 decreases. Therefore, in Embodiment 5, the above SN ratio can be increased, so that the above-described drive control for the vibration portion 21 can be more accurately performed.

### Effects of Embodiment 5

In Embodiment 5 as well, as in Embodiments 1 to 3, in each of the wiring regions A1, the low dielectric layer 115 (or the low dielectric layers 115 and 118) containing at least one element (component of the piezoelectric layer 112) forming the piezoelectric layer 112 is formed on the upper surface of the piezoelectric layer 112. Therefore, as in Embodiments 1 to 3, in each of the wiring regions A1, a voltage drop is caused by the low dielectric layer 115, and thus the voltage applied to the piezoelectric layer 112 in the wiring region A1 can be reduced. Accordingly, unnecessary displacement or stress is suppressed in the wiring region A1. Thus, damage to the wiring region A1 can be avoided, and the reliability of the drive element 1 can be increased.

Out of the upper surface region of each fixing part 10 and each drive part 20, the region on the drive part 20 side is divided into the drive regions A2 for driving and the detection regions A3 for detecting displacement of the drive regions A2, and the wiring regions A1 on the fixing part 10 side of the upper surface region are divided into the first wiring regions A11 connected to the drive regions A2 and the second wiring regions A12 connected to the detection regions A3. Accordingly, the drive state of each vibration portion 21 (drive part 20) can be detected using the detection signal based on the detection region A3.

As described with reference to FIG. 11 to FIG. 12B, the determination circuit 2b outputs a control signal for correcting the amplitude and the frequency of the voltage to be applied to the drive region A2, to the drive circuit 2c, using the detection signal based on the detection region A3. Accordingly, each vibration portion 21 is allowed to vibrate at appropriate vibration amplitude and frequency, and thus the drive state of the movable part 30 and the mirror 31 can be set to a desired state.

Since the low dielectric layer 115 (or the low dielectric layers 115 and 118) is placed in each second wiring region A12, the capacitance Cw in the second wiring region A12 can be effectively decreased. Accordingly, the above-described SN ratio can be increased, and thus the change in electric charge based on each detection region A3 can be accurately detected in the external device 2.

### Modifications of Embodiment 5

The layout of the drive regions A2 and the detection regions A3 is not limited to the layout shown in FIG. 9, and may be another layout.

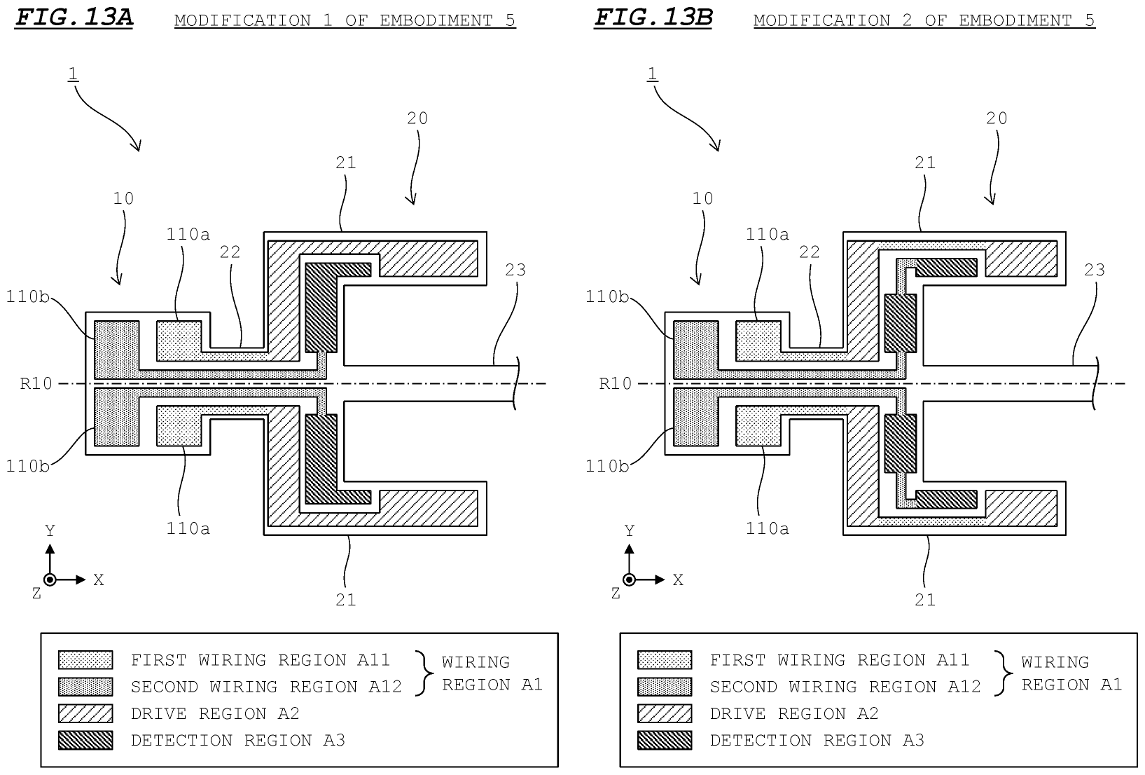

FIG. 13A is a plan view schematically showing a configuration of a drive element 1 according to Modification 1 of Embodiment 5. The drive element 1 of Modification 1 is configured to be line-symmetrical in the X-axis direction with the movable part 30 as a center. Thus, in FIG. 13A, for convenience, only a portion on the X-axis negative side of the movable part 30 is shown.

In Modification 1 in FIG. 13A, the drive regions A2 and the detection regions A3 each have an L-shape. In this case as well, a low dielectric layer is not placed in the drive regions A2 and the detection regions A3, and is placed in the wiring regions A1.

FIG. 13B is a plan view schematically showing a configuration of a drive element 1 according to Modification 2 of Embodiment 5. In FIG. 13B as well, for convenience, only a portion on the X-axis negative side of the movable part 30 is shown.

In Modification 2 in FIG. 13B, one drive region A2 is placed on a portion, of each vibration portion 21, extending in the X-axis direction, and one drive region A2 is placed on a portion, of each vibration portion 21, extending in the Y-axis direction. A first wiring region A11 connected to the fixing part 10 is connected to the drive region A2 closer to the rotation axis R10, and the two drive regions A2 are connected by another first wiring region A11. Similarly, one detection region A3 is placed on the portion, of each vibration portion 21, extending in the X-axis direction, and one detection region A3 is placed on the portion, of each vibration portion 21, extending in the Y-axis direction. A second wiring region A12 connected to the fixing part 10 is connected to the detection region A3 closer to the rotation axis R10, and the two detection regions A3 are connected by another second wiring region A12. The other first wiring region A11 and the other second wiring region A12 are configured in the same manner as the wiring region A1 and have a low dielectric layer.

Even with these configurations of Modifications 1 and 2, the same effects as those of Embodiment 5 described above can be achieved.

### Embodiment 6

In Embodiment 6, as in Embodiment 4, the drive parts 20 of the drive element 1 are each formed in a meander shape. Furthermore, in Embodiment 6, as in Embodiment 5, detection regions A3 for detecting drive of the drive parts 20 are formed.

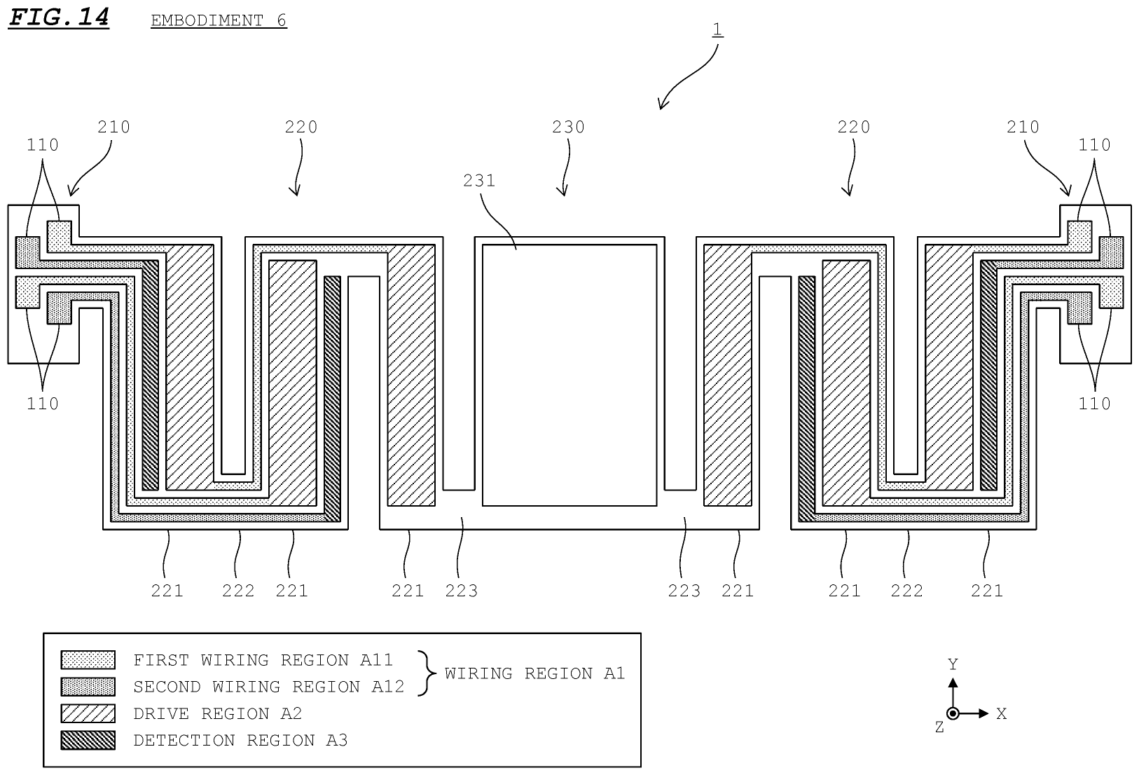

FIG. 14 is a plan view schematically showing a configuration of a drive element 1 according to Embodiment 6.

In the drive element 1 of Embodiment 6, as compared to Embodiment 4, detection regions A3 are placed on two vibration portions 221 on the outer side out of three vibration portions 221 aligned in the X-axis direction. The two detection regions A3 are connected to the fixing part 10 side by separate second wiring regions A12. Unlike Embodiment 4, the drive element 1 of Embodiment 6 is configured to be line-symmetrical in the X-axis direction with the movable part 230 as a center. Therefore, an end portion on the Y-axis negative side of the movable part 230 is supported by the drive part 220 on the X-axis positive side and the drive part 220 on the X-axis negative side. Each wiring region A1 of Embodiment 6 also has a low dielectric layer as in Embodiments 1 to 5 described above.

In Embodiment 6, among the vibration portions 221 aligned in the X-axis direction, the vibration portion 221 adjacent to the fixing part 210 and the vibration portion 221 adjacent to the movable part 230 are referred to as first vibration portions, and the vibration portion 221 between the first vibration portions is referred to as second vibration portion. When each drive part 220 is driven, voltages having opposite phases are applied to the drive regions A2 on the first vibration portions and the drive region A2 on the second vibration portion such that the first vibration portions and the second vibration portion vibrate in opposite directions in the Z-axis direction. At this time, the drive voltage to be applied to the drive regions A2 on the first vibration portions is corrected on the basis of a signal based on the outer detection region A3, and drive of the first vibration portions is controlled. Meanwhile, the drive voltage to be applied to the drive region A2 on the second vibration portion is corrected on the basis of a signal based on the inner detection region A3, and drive of the second vibration portion is controlled.

In Embodiment 6 as well, the same effects as those of Embodiments 4 and 5 are achieved.

### Modifications

In Embodiments 1 and 3, the metal layer 116 is made of titanium, but is not limited thereto, and may be made of any metal that can be changed to a low dielectric layer by thermal reaction. For example, the metal layer 116 may be made of zirconium, niobium, zinc, magnesium, or the like.

In Embodiments 1 to 6, the piezoelectric layer 112 is made of PZT (Pb(Zr, Ti)O₃), but is not limited thereto, and, for example, may be made of PbZrO₃, PbTiO₃, Pb(Mg_{1/3}, Nb_{2/3})O₃, or Pb(Zn_{1/3}, Nb_{2/3})O₃, or may be made of a solid solution of a combination thereof. That is, the piezoelectric layer 112 may contain at least one of PbZrO₃, PbTiO₃, Pb(Zr, Ti)O₃, Pb(Mg_{1/3}, Nb_{2/3})O₃, and Pb (Zn_{1/3}, Nb_{2/3})O₃. For example, when Pb (Mg_{1/3}, Nb_{2/3})O₃ or Pb(Zn_{1/3}, Nb_{2/3})O₃ is used in combination with at least one of PbZrO₃ and PbTiO₃, a piezoelectric constant is improved. In this case, the driving force and the driving amount of the drive element 1 can be improved as compared to the case where Pb(Mg_{1/3}, Nb_{2/3})O₃ or Pb (Zn_{1/3}, Nb_{2/3})O₃ is used alone.

Furthermore, it is also conceivable to use a non-lead ferroelectric material such as BiFeO₃ and KNbO₃ as the piezoelectric layer 112. In the case where a non-lead ferroelectric material is used as the piezoelectric layer 112, the same effects as above can be obtained by appropriately selecting the material of the metal layer 116 corresponding to the material of the piezoelectric layer 112 in Embodiment 1 or 3, or performing ion implantation and heat treatment in the same manner as above in Embodiment 2.

In Embodiments 1 to 6, the lower electrode 111 is formed from platinum, and the upper electrode 114 is formed from gold, but the materials forming the lower electrode 111 and the upper electrode 114 are not limited thereto. For example, the lower electrode 111 may be formed from iridium, lanthanum nickelate (LaNiO₃), strontium ruthenate (SrRuO₃), or the like. A lower electrode adhesion layer may be provided between the device layer 102 and the lower electrode 111. For example, the upper electrode 114 may be formed from platinum, aluminum, molybdenum, tungsten, iridium, lanthanum nickelate (LaNiO₃), strontium ruthenate (SrRuO₃), or the like. The upper electrode adhesion layer 113 is formed from nickel, but the material forming the upper electrode adhesion layer 113 is not limited thereto. For example, the upper electrode adhesion layer 113 may be formed from titanium, tungsten, or chromium.

In Embodiment 2, the upper portion of the piezoelectric layer 112 is changed to the low dielectric layer 115 by ion implantation and heat treatment, but the heat treatment may be omitted, and only the ion implantation may be performed on the upper portion of the piezoelectric layer 112. In this case as well, deficiency is caused in the perovskite structure of the upper portion of the piezoelectric layer 112, and thus this portion becomes the low dielectric layer 115 having no piezoelectricity.

In Embodiment 3, the low dielectric layer 115 is formed by applying heat to the metal layer 116 as in Embodiment 1, but alternatively, may be formed by performing ion implantation and heat treatment as in Embodiment 2.

In each of Embodiments 1 to 6, the pair of fixing parts 10 or 210 and the pair of drive parts 20 or 220 are placed in the X-axis direction with the movable part 30 or 230 as a center, but the fixing part 10 or 210 and the drive part 20 or 220 may be placed only on one side of the movable part 30 or 230.

In each of Embodiments 1 to 4, each vibration portion 21 or 221 is vibrated by supplying a voltage to the piezoelectric layer 112 in the drive region A2 from the fixing part 10 or 210 side, but a change in voltage caused in response to the vibration applied to the piezoelectric layer 112 in the drive region A2 may be outputted to the fixing part 10 or 210 side. That is, in each of Embodiments 1 to 3, an element having the configuration of the lamination structure 110 as described above may be used as a piezoelectric element that drives the vibration portion 21 and detects the vibration of the vibration portion 21. Similarly, in Embodiment 4, an element having the configuration of the lamination structure 110 as described above may be used as a piezoelectric element that drives the vibration portion 221 and detects the vibration of the vibration portion 221. In addition, an element having the configuration of the lamination structure 110 as described above may be used as a piezoelectric element that detects only the vibration of the vibration portion.

In addition to the above, various modifications can be made as appropriate to the embodiments of the present invention, without departing from the scope of the technological idea defined by the claims.

What is claimed is:

1. A drive element comprising:
a fixing part;
a drive part placed on a lateral side of the fixing part and coupled to the fixing part; and
a movable part configured to be driven by the drive part, wherein
a lower electrode, a piezoelectric layer, and an upper electrode are formed in order in an upper surface region of the fixing part and the drive part, and
in a wiring region on the fixing part side of the upper surface region, a low dielectric layer containing at least one element forming the piezoelectric layer is formed on an upper surface of the piezoelectric layer.

2. The drive element according to claim 1, wherein the low dielectric layer is a layer formed by thermally reacting the piezoelectric layer and a metal layer provided on the piezoelectric layer.

3. The drive element according to claim 1, wherein the low dielectric layer is a layer formed by performing ion implantation and heat treatment on the piezoelectric layer.

4. The drive element according to claim 3, wherein ions to be implanted include at least one of titanium, zirconium, niobium, zinc, and magnesium.

5. The drive element according to claim 1, wherein the piezoelectric layer contains at least one of PbZrO₃, PbTiO₃, Pb(Zr, Ti)O₃, Pb(Mg_{1/3}, Nb_{2/3})O₃, and Pb(Zn_{1/3}, Nb_{2/3})O₃.

6. The drive element according to claim 1, wherein the low dielectric layer contains more of a component or structure of the piezoelectric layer the closer it is to the piezoelectric layer.

7. The drive element according to claim 1, wherein an upper electrode adhesion layer is placed on an upper surface of the low dielectric layer in the wiring region and the upper surface of the piezoelectric layer in a drive region on the drive part side.

8. The drive element according to claim 7, wherein a metal contained in the low dielectric layer has a lower standard reaction Gibbs energy of oxide than that in the upper electrode adhesion layer.

9. The drive element according to claim 1, wherein an upper surface of the low dielectric layer in the wiring region and the upper surface of the piezoelectric layer in a drive region on the drive part side are at substantially the same height.

10. The drive element according to claim 1, wherein the low dielectric layer is multilayered.

11. The drive element according to claim 1, wherein the drive part has a tuning fork shape.

12. The drive element according to claim 1, wherein the drive part has a meander shape.

13. The drive element according to claim 1, wherein
a region on the drive part side of the upper surface region is divided into a drive region for driving and a detection region for detecting displacement of the drive region, and
the wiring region on the fixing part side of the upper surface region is divided into a first wiring region connected to the drive region and a second wiring region connected to the detection region.

14. The drive element according to claim 1, wherein a mirror is placed on the movable part.
